(19) United States
(12) Patent Application Publication
(10) Pub. No.: US 2017/0086290 A1
(43) Pub. Date: Mar. 23, 2017

(54) PREPREG, PRINTED CIRCUIT BOARD INCLUDING PREPREG, AND METHOD OF FABRICATING THE SAME

(71) Applicant: Samsung Electro-Mechanics Co., Ltd., Suwon-si (KR)

(72) Inventors: Keun-Yong LEE, Suwon-si (KR); Jun-Young KIM, Seoul (KR); Sa-Yong LEE, Suwon-si (KR); Sang-Hyun SHIN, Suwon-si (KR)

(73) Assignee: Samsung Electro-Mechanics Co., Ltd., Suwon-si (KR)

(21) Appl. No.: 15/099,212

(22) Filed: Apr. 14, 2016

Related U.S. Application Data
(60) Provisional application No. 62/220,500, filed on Sep. 18, 2015.

(51) Int. Cl. H05K 1/02; H05K 3/00; H05K 3/46; H05K 1/09; H05K 1/03

(52) U.S. Cl. CPC H05K 1/0271; H05K 1/09; H05K 1/0298; H05K 1/0366; H05K 1/0306; H05K 3/4652; H05K 3/0011; H05K 2203/1333; H05K 2201/0275

(57) ABSTRACT

A prepreg, a printed circuit board and a method of manufacturing the same are provided. A prepreg includes a core layer including nanofibers having a thickness in a range of 10 to 100 nm, a first insulating layer on a first surface of the core layer, and a second insulating layer on a second surface of the core layer.

### CROSS REFERENCE TO RELATED APPLICATION

This application claims the benefit of priority under 35 USC 119(e) of U.S. Provisional Patent Application No. 62/220,500 filed on Sep. 18, 2015, the entire disclosure of which is incorporated herein for all purposes.

### BACKGROUND

1. Field

The following description relates to a prepreg, a printed circuit board including a prepreg, and a method to fabricate the same. For example, the following description relates to a prepreg that exhibits reliability even when produced to have a thin thickness and a method to fabricate such a prepreg. The following description also relates to a printed circuit board manufactured with such a prepreg, and a method to fabricate the printed circuit board.

2. Description of Related Art

With the advancement of electronic technologies, printed circuit boards are becoming lighter, thinner and smaller. In printed circuit boards, patterns for connecting circuits and insulating layers for providing insulation between patterns are alternatively laminated. Patterns are usually formed of a conductor or a metal such as copper, and insulating layers are often formed of a resin or an epoxy resin.

The insulating layers are limited to have certain thickness to produce a printed circuit board having a desired thickness. However, when the thickness of the insulating layer is reduced to produce a slim printed circuit board, warpage may occur in the printed circuit board. Since the patterns and insulating layers of a printed circuit board generally exhibit different coefficients of thermal expansion, glass transition temperatures, modules and the like, it is difficult to avoid warpage of the printed circuit board when printed circuit boards are reduced in thickness. This may further deteriorate electrical, thermal, and mechanical stabilities of printed circuit boards.

When the thickness of a printed circuit board becomes thinner, the quality of the printed circuit board is deteriorated, and a dielectric constant (Dk) and a dissipation factor (Df) may be also reduced. When an electronic component is mounted on such a printed circuit board, the deteriorated quality of the printed circuit board may result in signal transmission defects and warpage problems.

To maintain the quality of a printed circuit board while reducing its thickness, glass transition temperature, modulus and stiffness of a core layer disposed within the printed circuit board need to be increased. A thick copper clad laminate including a core layer formed of a fabric cloth or glass cloth or a build-up layer formed of a resin can be formed to prevent the warpage and to increase dimensional stability.

Various inorganic fillers can be added to the resin to further improve physical properties. However, in this case, the adhesion to a copper layer forming a pattern is deteriorated, and stability of the patterns and reliability are also reduced. In KR Patent Publication No 2013-0119643, a printed circuit board with a heat-radiating substrate having an electrical-isolated thermal bridge and a method for fabricating the same are disclosed.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a prepreg includes a core layer comprising nanofibers having a thickness in a range of 10 to 100 nm, a first insulating layer on a first surface of the core layer, and a second insulating layer on a second surface of the core layer.

The core layer may include one selected from the group consisting of an aramid-based organic material, nylon, a silica-based inorganic material and a titania-based inorganic material.

A portion of a material forming the first insulating layer, the second insulating layer or both may be impregnated into the core layer.

The nanofiber may be a hollow fiber.

A portion of a material forming the first insulating layer, the second insulating layer or both may be impregnated into the hollow of the hollow fiber.

A thickness of the first insulating layer is different from a thickness of the second insulating layer.

In another general aspect, a printed circuit board includes a general aspect of a prepreg described above, and a base layer disposed on at least one of the first insulating layer and the second insulating layer of the prepreg.

The base layer may include a copper foil.

In another general aspect, a method for manufacturing a prepreg involves obtaining a first insulating layer disposed on a copper foil, forming a core layer comprising nanofibers on the first insulating layer, and forming a second insulating layer on the core layer.

The nanofibers may have a thickness in a range of 10 to 100 nm.

The core layer may include one selected from the group consisting of an aramid-based organic material, nylon, a silica-based inorganic material and a titania-based inorganic material.

The forming of the second insulating layer on the core layer may involve impregnating a portion of a material that forms the second insulating layer into the core layer.

The nanofibers may be hollow fibers.

The forming of the second insulating layer on the core layer may involve impregnating a portion of a material that forms the second insulating layer into the hollow of the hollow fiber.

A thickness of the second insulating layer may be different from a thickness of the first insulating layer.

In another general aspect, a method for manufacturing a printed circuit board involves forming a base layer on at least one of the first insulating layer and the second insulating layer of the prepreg manufactured according to the general aspect of the method of manufacturing a prepreg described above.

The base layer may include a copper foil.

In yet another general aspect, a method for manufacturing a prepreg involves electrospinning nanofibers on a first insulating layer to form a core layer, and forming a second insulating layer on the core layer.

Prior to the electrospinning of the nanofibers on the first insulating layer, the first insulating layer may be formed on a base layer comprising copper.

A thickness of the nanofibers in the core layer may be in a range of 10 to 100 nm.

Other features and aspects will be apparent from the following detailed description, the drawings, and the claims.

### BRIEF DESCRIPTION OF THE DRAWINGS

FIG. 1 is a sectional view illustrating an example of a printed circuit board.

FIGS. 2 to 5 are sectional views illustrating an example of a method for manufacturing a printed circuit board.

FIG. 6 is an in-plane transmission electron microscope image illustrating nanofibers of a core layer that is applied in an example of a printed circuit board.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Unless otherwise defined, all terms, including technical terms and scientific terms, used herein have the same meaning as how they are generally understood by those of ordinary skill in the art to which the present disclosure pertains. Any term that is defined in a general dictionary shall be construed to have the same meaning in the context of the relevant art, and, unless otherwise defined explicitly, shall not be interpreted to have an idealistic or excessively formalistic meaning.

Identical or corresponding elements will be given the same reference numerals, regardless of the figure number, and any redundant description of the identical or corresponding elements will not be repeated. Throughout the description of the present disclosure, when describing a certain relevant conventional technology is determined to evade the point of the present disclosure, the pertinent detailed description will be omitted. Terms such as “first” and “second” can be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

Hereinafter, certain embodiments of the present disclosure will be described in detail with reference to the accompanying drawings.

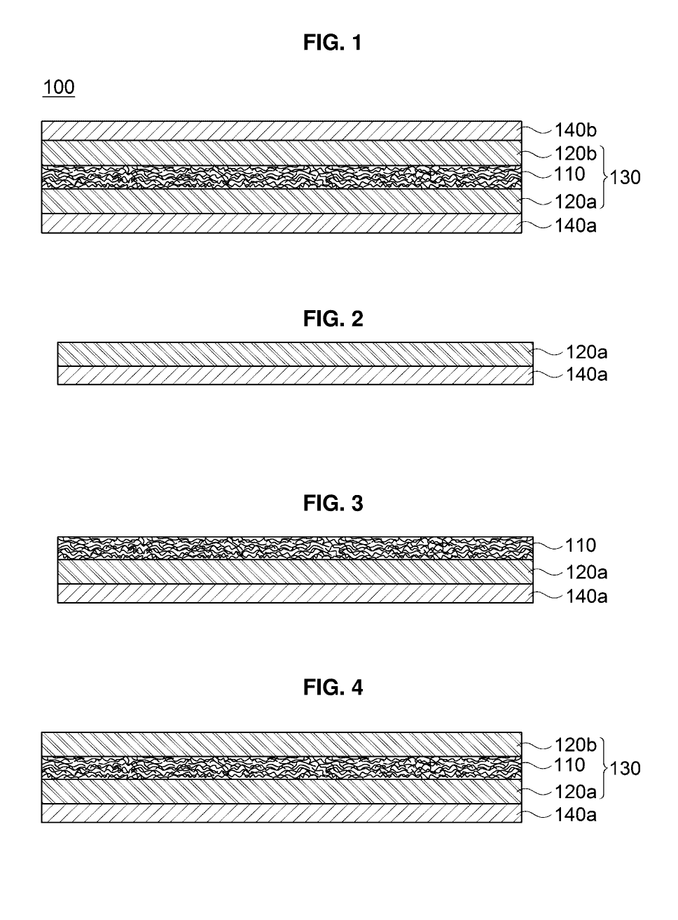

FIG. 1 is a sectional view illustrating an example of a printed circuit board.

Referring to FIG. 1, a printed circuit board 100 includes a core layer 110, insulating layers 120a, 120b formed on both surfaces of the core layer 110, and base layers 140a, 140b formed on the insulating layers 120a, 120b, respectively.

The core layer 110 may be formed of nanofibers obtained via an electrospinning method. For example, the core layer 110 may be formed by electrospinning a solution in which an organic or inorganic material is dissolved. Examples of suitable organic or inorganic material for electrospinning include an aramid-based organic material, nylon, a silica-based inorganic material and a titania-based inorganic material.

According to an example in which an aramid-based organic material is used to electrospin the nanofibers, the core layer 110 may exhibit high stiffness and high modulus while reducing warpage of the printed circuit board 100 produced with the core layer. According to an example in which nylon is used to obtain the core layer 110, a hollow fiber may be formed, and a dielectric constant (Dk) and a dissipation factor (Df) of the core layer 110 may be lowered due to the air in hollows of the fiber. According to an example in which a silica-based inorganic material or titania-based inorganic material is used in the core layer 110, the printed circuit board 100 may exhibit a low coefficient of thermal expansion and a high modulus, and the dielectric constant (Dk) and the dissipation factor (Df) may become lowered depending on other additives. 110

The core layer 110 may be formed of nanofibers having a thickness of about 10 nm to 100 nm. Since the nanofibers are physically entangled to have a porous nanofiber structure, the core layer 110 may be formed as a thin film to improve modulus of the printed circuit board 100, while maintaining the coefficient of thermal expansion to be low.

When the thickness of the nanofibers in the core layer 110 is set to be lower than 10 nm, the core layer 110 may not be formed in a network structure, and thus the desired modulus may not be obtained. On the other hand, when the thickness of the nanofibers is greater than 100 nm, the adhesiveness between the core layer 110 and the insulating layers 120a, 120b may be low. Thus, according to one example, the nanofibers may be electrospun to obtain a core layer 110 in which the nanofibers have a thickness of 10 nm to 100 nm.

According to one example, electrospinning may be performed under a high voltage of 5 to 25 kV, and a heat treatment may be performed by gradually increasing the temperature from a first temperature in the range of 10 to 30° C. to a second temperature in the range of 300 to 400° C. at a rate of 2 to 6° C. after the nanofiber is electrospun on the insulating layer 120a, to cause a thermal imidization of the nanofibers.

The insulating layers 120a, 120b may be laminated on the upper surface and the lower surface of the core layer 110, respectively to form the prepreg 130. The insulating layers 120a, 120b may be formed by laminating an insulating resin, such as an epoxy, on the upper surface and the lower surface of the core layer 110 and then hardening the resulting layers. The insulating layers 120a, 120b may improve the modulus of the printed circuit board 100 by impregnating an insulating resin to a glass cloth or fabric cloth.

Because the core layer 110 as described above may be formed as a thin film while maintaining the mechanical, thermal and electrical properties of the layer, a prepreg 130 with a thin thickness may be obtained.

The base layers 140a, 140b may be formed on the insulating layer 120a, 120b, respectively. Based on the type of printed circuit board 100 being manufactured, the base layers 140a, 140b may be formed of a copper foil. The layers 140a, 140b may be formed of an insulating resin that may be the same as or different from the material of the insulating layer 120a, 120b.

The insulating layers 120a, 120b may be formed to have different thicknesses, and this different thickness of the insulating layers 120a, 120b may reduce or eliminate warpage of the printed circuit board 100.

The insulating layers 120a, 120b may be independently formed of a thermosetting resin or thermoplastic resin. For example, the insulating layer 120a may be formed of a thermosetting resin, and the insulating layer 120b may be formed of a thermoplastic resin.

When the base layers 140a, 140b are formed of a copper foil, a copper clad laminate, in which the copper foil is formed on both surfaces of the prepreg 130, may be formed. In this example, the copper foil of the copper clad laminate may be patterned. When the base layers 140a, 140b are formed of an insulating resin, build-up layers of the multilayer printed circuit board may be formed.

According to one example, the nanofibers forming the core layer 110 may be formed to have a hollow fiber shape. In that case, because the hollow space within the hollow fiber may be filled with air, an insulating layer with a low dielectric constant may be obtained. Further, the printed circuit board 100 formed thereby may be favorable in high-frequency and high-speed transmission.

FIGS. 2 to 5 illustrate sectional views illustrating an example of a method for manufacturing a printed circuit board, and FIG. 6 is an in-plane transmission electron microscope image illustrating nanofibers of an example of a core layer that is applied to a printed circuit board.

Referring to FIG. 2, a lower base layer 140a, on which a lower insulating layer 120a is formed, is prepared. The lower base layer 140a may be formed of a copper foil or an insulating plate that is a hardened insulating resin. The lower insulating layer 120a may be formed on a surface of the base layer 140a in a thickness of several micrometers. The lower insulating layer 120a may have, for example, a thickness of approximately 2-10 μm, 3-8 μm, or 5-8 μm to produce a prepreg having a desired thickness and mechanical strength.

Referring to FIG. 3, the core layer 110 composed of nanofibers is formed on the lower insulating layer 120a. The core layer 110 may be an entangled nanofiber layer formed by electrospinning nanofibers on the lower insulating layer 120a.

The electrospinning process may produce spinning-produced continuous nanofiber filament bundles with a minimum diameter in the nanoscale. The core layer 110 in which nanofibers are arranged randomly may be formed by ejecting nanofibers through a nozzle at a constant speed, as shown in FIG. 6.

The core layer 110 formed through the electrospinning method may be formed in a thickness of about 10 nm to 100 nm on the lower insulating layer 120a. The core layer 110 may exhibit a high specific surface area per unit volume so that the insulating layer with high stiffness may be formed.

When nanofibers are laminated through the electrospinning method to form the core layer 110, the size of the pore spaces may be controlled by arranging the nanofibers randomly by mixing polymers having different solubilities in the polymer solutions that are applied to an electrospinning apparatus and then selectively eliminating one polymer to form the pores.

The core layer 110 formed on the lower insulating layer 120a may be formed by utilizing nanofibers with a hollow fiber shape. The nanofibers with a hollow fiber shape may be formed when the nozzle of the electrospinning apparatus has a dual structure. The hollows of the hollow fibers may form air gaps to improve the dielectric constant of the core layer 110.

Referring to FIG. 4, an upper insulating layer 120b is further formed on the core layer 110 that is provided on the lower insulating layer 120a. The core layer 110 and the lower and upper insulating layers 120a, 120b together form a prepreg 130 having the core layer 110 at the center. The prepreg 130 may be used as the core of a printed circuit board 100 due to the high modulus and low coefficient of thermal expansion of the core layer 110. A prepreg 130 may be also applied to build-up layers of a multilayer printed circuit board, for example, for the purpose of preventing warpage.

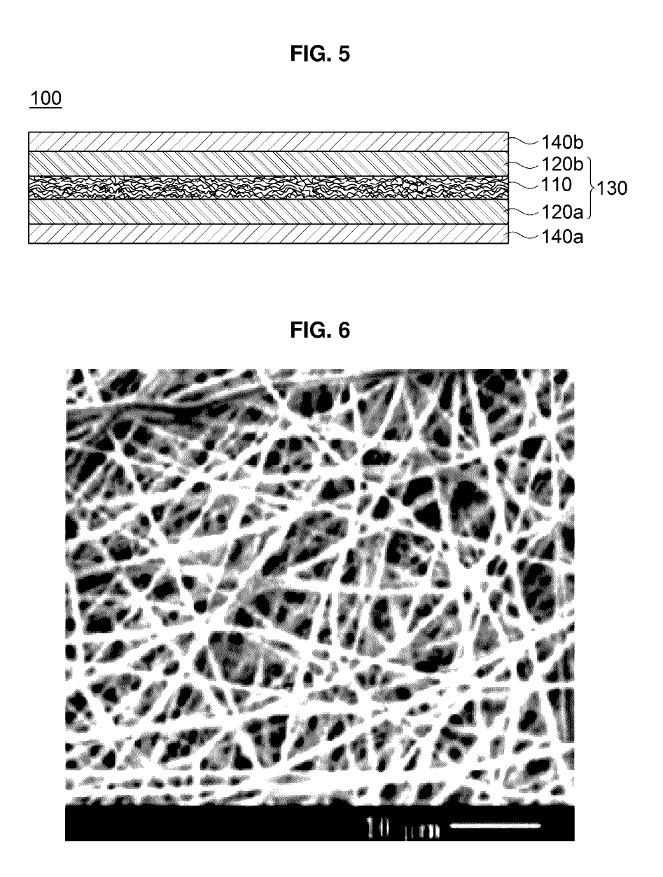

Referring to FIG. 5, an upper base layer 140b that is formed of the same material as the lower base layer 140a may be formed on the upper insulating layer 120b to form a copper clad laminate or a build-up layer of the printed circuit board.

An example of a printed circuit board prepared as described above may include a core layer 110 having a relatively flat surface and low flexibility. When the insulating layers 120a, 120b are formed on the upper surface and the lower surface of the core layer 110, the surfaces of the insulating layer 120a, 120b may be smooth and thus reduce a defect rate when additional insulating layer(s) or plating layer is formed on the insulating layers 120a, 120b.

During the process of forming the core layer 110, a layer of organic nanofibers may be further formed between the core layer 110 in which the inorganic nanofibers are randomly arranged and the insulating layers 120a, 120b. By forming the organic nanofiber layer, the adhesiveness between the core layer 110 and the insulating layers 120a, 120b may be improved. When the insulating layers 120a, 120b are formed of an organic insulating material and both surfaces of the core layer 110 are formed of organic nanofibers including the same organic materials as the insulating layers 120a, 120b, the adhesiveness between the core layer 110 and the insulating layers 120a, 120b may be improved.

According to an example of a prepreg described above, the prepreg exhibits a low coefficient of thermal expansion while maintaining a high modulus.

According to another example described above, a method for manufacturing a prepreg results in a prepreg having a low coefficient of thermal expansion and a high modulus.

According to another example described above, a printed circuit board formed using the above described prepreg exhibits a low coefficient of thermal expansion and a high modulus.

According to another example described above, a method for manufacturing a printed circuit board is provided in which the prepreg exhibits a low coefficient of thermal expansion while maintaining a high modulus.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A prepreg comprising:
a core layer comprising nanofibers having a thickness in a range of 10 to 100 nm;
a first insulating layer on a first surface of the core layer; and
a second insulating layer on a second surface of the core layer.

2. The prepreg of claim 1, wherein the core layer comprises one selected from the group consisting of an aramid-based organic material, nylon, a silica-based inorganic material and a titania-based inorganic material.

3. The prepreg of claim 1, wherein a portion of a material forming the first insulating layer, the second insulating layer or both is impregnated into the core layer.

4. The prepreg of claim 1, wherein the nanofiber is a hollow fiber.

5. The prepreg of claim 4, wherein a portion of a material forming the first insulating layer, the second insulating layer or both is impregnated into the hollow of the hollow fiber.

6. The prepreg of claim 1, wherein a thickness of the first insulating layer is different from a thickness of the second insulating layer.

7. A printed circuit board comprising:
a prepreg of claim 1; and
a base layer disposed on at least one of the first insulating layer and the second insulating layer of the prepreg.

8. The printed circuit board of claim 7, wherein the base layer comprises a copper foil.

9. A method for manufacturing a prepreg, the method comprising:
obtaining a first insulating layer disposed on a copper foil;
forming a core layer comprising nanofibers on the first insulating layer; and
forming a second insulating layer on the core layer.

10. The method of claim 9, wherein the nanofibers have a thickness in a range of 10 to 100 nm.

11. The method of claim 9, wherein the core layer comprises one selected from the group consisting of an aramid-based organic material, nylon, a silica-based inorganic material and a titania-based inorganic material.

12. The method of claim 9, wherein the forming of the second insulating layer on the core layer comprises impregnating a portion of a material that forms the second insulating layer into the core layer.

13. The method of claim 9, wherein the nanofibers are hollow fibers.

14. The method of claim 13, wherein the forming of the second insulating layer on the core layer comprises impregnating a portion of a material that forms the second insulating layer into the hollow of the hollow fiber.

15. The method of claim 9, wherein a thickness of the second insulating layer is different from a thickness of the first insulating layer.

16. A method for manufacturing a printed circuit board, the method comprising forming a base layer on at least one of the first insulating layer and the second insulating layer of the prepreg manufactured according to claim 9.

17. The method of claim 16, wherein the base layer comprises a copper foil.

18. A method for manufacturing a prepreg, the method comprising:
electrospinning nanofibers on a first insulating layer to form a core layer; and
forming a second insulating layer on the core layer.

19. The method of claim 18, wherein, prior to the electrospinning of the nanofibers on the first insulating layer, the first insulating layer is formed on a base layer comprising copper.

20. The method of claim 18, wherein a thickness of the nanofibers in the core layer is in a range of 10 to 100 nm.
